(19) United States
(12) Patent Application Publication
(10) Pub. No.: US 2005/0230673 A1
(43) Pub. Date: Oct. 20, 2005

(54) Colloidal quantum dot light emitting diodes

(76) Inventors: Alexander H. Mueller, Santa Fe, NM (US); Mark A. Hoffbauer, Los Alamos, NM (US); Victor I. Klimov, Los Alamos, NM (US)

Correspondence Address: UNIVERSITY OF CALIFORNIA;LOS ALAMOS NATIONAL LABORATORY, P.O. BOX 1663, MS A187, LOS ALAMOS, NM, 87545, US

(21) Appl. No.: 11/089,726

(22) Filed: Mar. 25, 2005

Related U.S. Application Data
(60) Provisional application No. 60/556,591, filed on Mar. 25, 2004.

(51) Int. Cl. H01L 29/06

(52) U.S. Cl. 257/13

(57) ABSTRACT

The present invention is directed to light emitting devices including a first layer of a semiconductor material from the group of a p-type semiconductor and a n-type semiconductor, a layer of colloidal nanocrystals on the first layer of a semiconductor material, and, a second layer of a semiconductor material from the group of a p-type semiconductor and a n-type semiconductor on the layer of colloidal nanocrystals.

This application claims the benefit of provisional application Ser. No. 60/556,591 filed Mar. 25, 2004.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates to electronic devices such as light emitting diodes containing colloidal quantum dots. More particularly, the present invention relates to inorganic based light emitting diodes containing colloidal quantum dots.

### BACKGROUND OF THE INVENTION

Solid-state, light-emitting devices play an increasingly important role in numerous technologies from displays to optical communication and traffic signals. Progress in light emitting diode (LED) technology, first introduced in the 1960's, has led to devices with enhanced reliability, power conversion efficiency, and brightness across a wide range of colors. However, semiconductor LEDs remain relatively expensive, particularly in the cases of large-area and/or high power applications. As a lower cost alternative to semiconductor devices, organic-molecule-based LEDs (OLEDs) were introduced in the 1980's. Due to the ease in processing allowed by chemical synthesis, OLEDs are well suited for large-area applications and applications requiring flexible substrates. OLEDs are usually fabricated using pi-conjugated molecules such as tris-(8-hydroxyquinolate)-aluminum (Alq) or poly(para-phenylene vinylene) (PPV). While Alq and PPV are efficient emitters, they are prone to photodegradation due to loss of conjugation.

Light-emitting diodes and related devices which incorporate quantum dots use dots which have typically been grown on a semiconductor layer using molecular beam epitaxy (MBE) or metallorganic chemical vapor deposition (MOCVD). However, the processing costs of such quantum dots by currently available methods are quite high. Colloidal production of quantum dots is a much less expensive process, but these dots have not generally been able to be integrated into traditional semiconductor growth technologies, and thus have not generally been incorporated into light-emitting diodes.

U.S. Pat. No. 6,501,091 describes embedding colloidally produced quantum dots in a host matrix that may be a polymer such as polystyrene, polyimide, or epoxy, a silica glass, or a silica gel, in order to use the electroluminescence of these types of quantum dots for an LED.

U.S. Pat. No. 6,665,329 describes use of nanocluster materials such as molybdenum disulfide (MoS₂), and group II-VI semiconductors such as cadmium sulfide, cadmium selenide, zinc sulfide and zinc selenide in conjunction with an ultraviolet emitting aluminum gallium nitride based light emitting diode, the nanocluster materials situated on the opposite side of a sapphire substrate from the p-doped and n-doped gallium nitride layers. The nanocluster materials have strong absorption in the ultraviolet wavelength range and strong emission in the visible wavelength range.

Despite the gradual progress, problems have remained. After careful research, new approaches have now been developed for the preparation of colloidal nanocrystal-containing light emitting devices.

It is an object of the present invention to provide a light emitting device incorporating colloidal nanocrystals between layers of n- and p-type inorganic semiconductor materials.

It is another object of the present invention to provide a light emitting device incorporating or embedding colloidal nanocrystals into one layer of either n- or p-type inorganic semiconductor materials.

### SUMMARY OF THE INVENTION

In accordance with the purposes of the present invention, as embodied and broadly described herein, the present invention provides a light emitting device including a first layer of a semiconductor material selected from the group consisting of a p-type semiconductor and a n-type semiconductor, a layer of colloidal nanocrystals on said first layer of a semiconductor material, and, a second layer of a semiconductor material selected from the group consisting of a p-type semiconductor and a n-type semiconductor on said layer of colloidal nanocrystals, the second layer of a semiconductor material being a p-type semiconductor where the first layer of a semiconductor material is a n-type semiconductor or being a n-type semiconductor where the first layer of a semiconductor material is a p-type semiconductor. In one embodiment, the colloidal nanocrystals are embedded within a semiconductor layer, either the p-type semiconductor layer or the n-type semiconductor layer.

The present invention still further provides a light emitting device including an injection layer including colloidal nanocrystals embedded in an semiconductor material selected from the group consisting of a p-type semiconductor and a n-type semiconductor.

### BRIEF DESCRIPTION OF THE DRAWINGS

FIG. 1 shows a schematic illustration of a fabrication process for preparation of a quantum dot light emitting diode.

FIG. 2 shows a schematic illustration of a quantum dot light emitting diode.

FIG. 3 shows a schematic diagram of band gap energies from the quantum dot light emitting diode of FIG. 1.

FIG. 4 shows a graph comparing electroluminescence (EL) and photoluminescence (PL) spectra from a quantum dot diode as shown in FIG. 1.

FIG. 5 shows a schematic diagram of co-deposition of evaporated metal atoms with energetic neutral atoms on a substrate.

FIG. 6 shows a graph illustrating EL intensity versus voltage and current for examination of carrier injection into the quantum dots.

### DETAILED DESCRIPTION

The present invention is concerned with electronic devices such as LEDs including colloidal quantum dots or nanocrystals and with processes of forming such devices. The present invention is further concerned with encapsulation of colloidal quantum dots or nanocrystals within inorganic semiconductor films formed at low temperatures generally as low as about 300° C., and preferably less than about 300° C.

Semiconductor nanocrystals (NCs), often referred to as nanocrystal quantum dots (NQDs), are of interest for their size-tunable optical and electronic properties. Intermediate between the discrete nature of molecular clusters and the collective behavior of the bulk, NQDs are unique building blocks for the bottom-up assembly of complex functional structures. NQDs can be conveniently synthesized using colloidal chemical routes such as the solution-based organometallic synthesis approaches for the preparation of CdSe NQDs described by Murray et al., J. Am. Chem. Soc., 115, 8706 (1993) or by Peng et al., J. Am. Chem. Soc., 123, 183 (2001), such references incorporated herein by reference. Generally, these procedures involve an organometallic approach. Typically these chemical routes yield highly crystalline, monodisperse samples of NQDs. Because of their small dimensions (sub-10 nm) and chemical flexibility, colloidal NQDs can be viewed as tunable “artificial” atoms and as such can be manipulated into larger assemblies engineered for specific applications.

As used herein, the terms “quantum dot” and “nanocrystal” are used interchanably and refer to particles less than about 15 nanometers in the largest axis, and preferably from about 1 to about 15 nanometers. Also, within a particularly selected colloidal nanocrystal, the colloidal nanocrystals are substantially monodisperse, i.e., the particles have substantially identical size and shape.

The colloidal nanocrystals are generally members of a crystalline population having a narrow size distribution. The shape of the colloidal nanocrystals can be a sphere, a rod, a disk and the like. The colloidal nanocrystals can include a core of a binary semiconductor material, e.g., a core of the formula MX, where M can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. Further, the colloidal nanocrystals can include a core of a ternary semiconductor material, e.g., a core of the formula M₁M₂X, where M₁ and M₂ can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. Still further, the colloidal nanocrystals can include a core of a quaternary semiconductor material, e.g., a core of the formula M₁M₂M₃X, where M₁, M₂ and M₃ can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. In some instances, the colloidal nanocrystals may be of silicon, germanium or silicon/germanium alloys. Examplary materials for the colloidal nanocrystals include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum sulfide (AlS), aluminum phosphide (AlP), aluminum arsenide (AlAs), aluminum antimonide (AlSb), lead sulfide (PbS), lead selenide (PbSe), lead telluride (PbTe), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN) and the like, mixtures of such materials, or any other semiconductor or similar materials.

Additionally, the core of any nanocrystalline semiconductor material can have an overcoating on the surface of the core. The overcoating can also be a semiconductor material, such an overcoating having a composition different than the composition of the core. The overcoat on the surface of the colloidal nanocrystals can include materials selected from among Group II-VI compounds, Group II-V compounds, Group III-VI compounds, Group III-V compounds, Group IV-VI compounds, Group I-III-VI compounds, Group II-IV-V compounds, and Group II-IV-VI compounds. Examples include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), lead sulfide (PbS), lead selenide (PbSe), lead telluride (PbTe), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN) and the like, mixtures of such materials, or any other semiconductor or similar materials. The overcoating upon the core material can include a single shell or can include multiple shells for selective tuning of the properties. The multiple shells can be of differing materials.

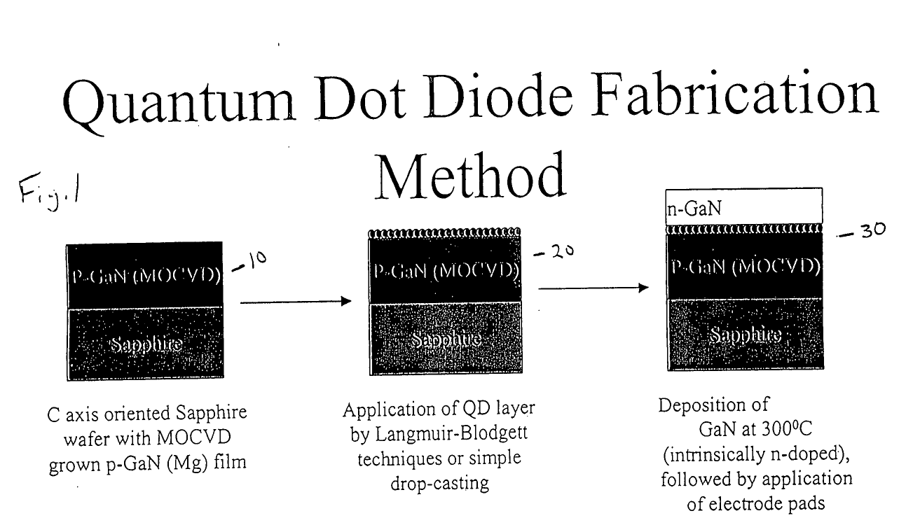

FIG. 1 shows a schematic illustration of a fabrication process for preparation of a quantum dot device, i.e., light-emitting diode. Initially, a suitable substrate, such as sapphire can have a layer of a p-type semiconductor, e.g., a Mg-doped GaN film, grown thereon to yield intermediate substrate 10. Such a p-type semiconductor can be grown via MOCVD as is well known to those skilled in the art. Thereafter, a layer of quantum dots having the desired size can be applied onto intermediate substrate 10 to yield structure 20. The layer of quantum dots can be applied by standard Langmuir-Blodgett techniques, by drop-casting, by spin coating, by self-assembly or other suitable processes. Then a layer of n-type semiconductor, e.g., a (doped or intrinsic) GaN film, can be grown thereon to structure 30. Preferably, such an n-type GaN film can be deposited at low temperatures, i.e., at temperatures of less than about 500° C., more preferably at temperatures of less than about 300° C. One manner of such depositions of GaN layers involves use of an energetic neutral atom beam process. Such a process can grow the desired GaN films at lower temperatures such as less than about 500° C. as opposed to the higher temperatures of at least about 800° C. necessary for a MOCVD process.

The structure shown in FIG. 1 can be reversed, i.e., an n-type semiconductor layer, e.g., a GaN film, can be formed on a substrate followed by deposition of a quantum dot layer and a p-type semiconductor layer, e.g., a Mg-doped GaN film deposited over the quantum dot layer. Also, the quantum dot layer may be embedded within the top layer of semiconductor, whether n-type or p-type by co-deposition with that semiconductor layer.

Preferably, the quantum dot layer has uniform complete coverage upon the semiconductor layer on which it is applied. Such uniform complete coverage yields better light output from the quantum dot layer without any shorting that can result from gaps in that layer. Such uniform complete coverage also prevents direct injection of electrons into the p-type layer and holes in the n-type layer, which would otherwise produce undesired recombination channels in the injection layers.

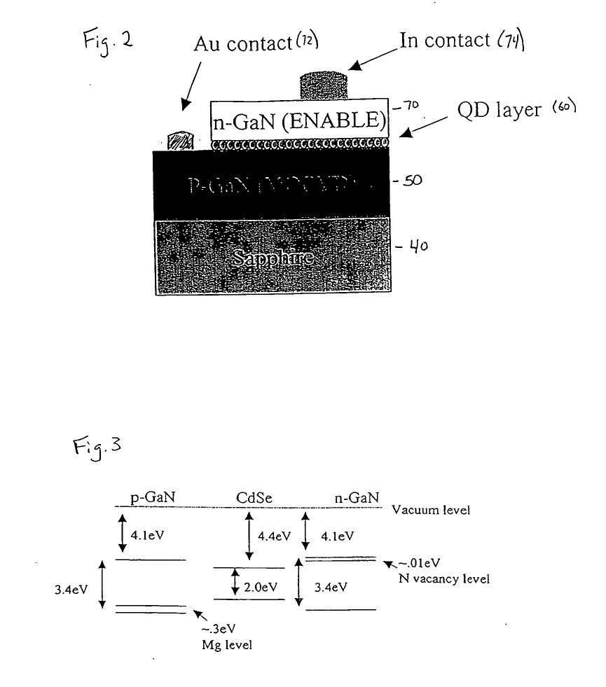

FIG. 2 shows a schematic illustration of a quantum dot device, i.e., diode including a sapphire substrate 40, a p-type GaN layer 50, e.g., a Mg-doped GaN film formed through MOCVD, a colloidal quantum dot layer 60, and a layer of n-type GaN 70. Gold contact 72 on p-type GaN layer 50 and indium contact 74 on n-type GaN layer 70 can be connected through a power source such as a battery to complete the device.

The device may further include tunnel barriers consisting of AlₓGal₁₋ₓN layers of a thickness such as to be described as “pseudomorphic”, i.e., the layers are not thick enough to have relaxed to their bulk lattice constant. This results in an enhanced band offset between the layers (in addition to the layer already having a larger band-width). Depending on whether hole or electron tunneling is the problem, the layers may be either grown on both sides of the active region (in this case the NCs) to reduce hole leakage, or on the n-GaN side in order to reduce electron leakage by “slowing” the electrons before they enter the active region, and blocking holes from leaving the active region. Thicknesses for such pseudomorphic layers are generally from about 20 nm to about 50 nm. The optical quality of these layers may be enhanced by adding a slight amount of indium (In). Such layers are sometimes referred to as “cladding”.

GaN films grown using the energetic neutral atom beam lithography/epitaxy process have been found by x-ray diffraction (XRD) analysis to have comparable peak widths, and less misorientation than GaN films grown by MOCVD with buffer layers.

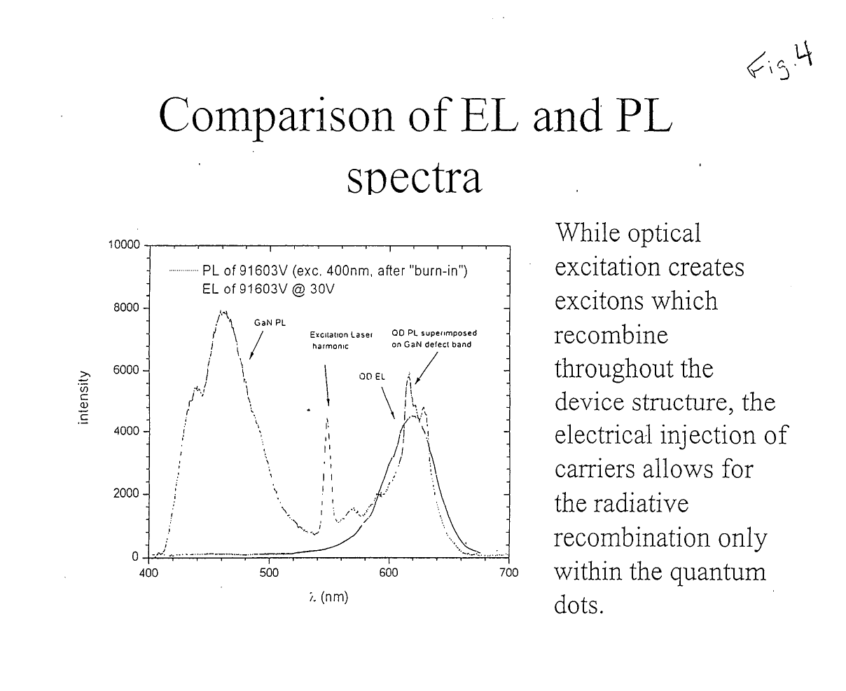

FIG. 3 shows a schematic diagram of band gap energies from a quantum dot diode such as shown in FIGS. 1 and 2.

Semiconductor films such as GaN can be deposited using an energetic neutral atom beam lithography/epitaxy process. The apparatus suitable for such depositions has been described previously by Cross et al. in U.S. Pat. No. 4,780,608 wherein the specifically described energetic neutral atoms were oxygen atoms. In the present invention, nitrogen gas can be used to generate energetic neutral atoms of nitrogen. The energies of such nitrogen atoms can generally be varied from about 0.5 eV to about 3 eV. One important modification to the apparatus shown in FIG. 1 of Cross et al. is the repositioning of the inlet valve for any flowing gas mixture from flow controllers 42 and 44 to the right (upstream) of lens 12. Such a repositioning has been found critical to extend the lifetime of the lens.

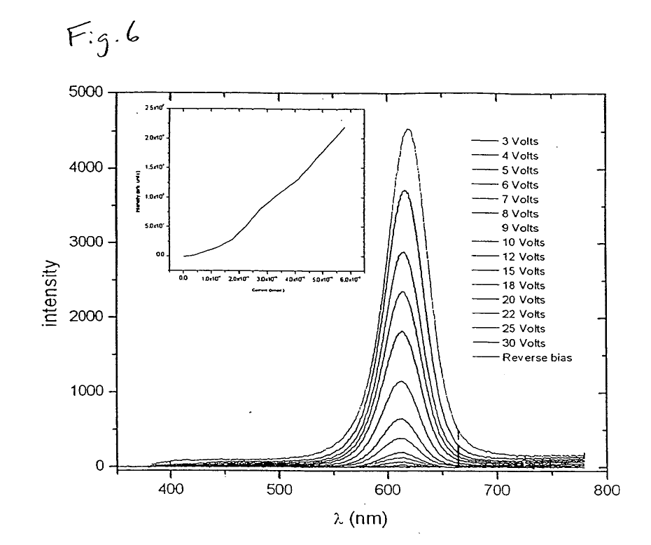

Film growth using metal co-deposition as shown in FIG. 5 involves simultaneous aluminum (Al), gallium (Ga) and/or indium (In) e-beam evaporation onto a substrate with exposure to incident energetic atoms, e.g., nitrogen atoms. Films of AlN, GaN, InN and ternary or quaternary compositions thereof can be formed on substrates of sapphire, silicon, glass, other semiconductor materials, and some polymers. Such films can be grown at high energetic N-atom fluxes that yield high growth rates, e.g., up to or exceeding about 1 micron per hour. Because of the simple chemistry used, the resultant films generally possess low impurity levels and can have high optical quality.

For the processes of the present invention, the colloidal nanocrystals can include all types of nanocrystals capped with suitable ligands or overcoated with additional layers of semiconductors (core—shell structures), including, e.g., semiconductor NQDs such as cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), lead sulfide (PbS), lead selenide (PbSe), lead telluride (PbTe), and mixtures of such materials.

The present invention is more particularly described in the following examples which are intended as illustrative only, since numerous modifications and variations will be apparent to those skilled in the art.

CdSe and (CdSe)ZnS core-shell colloidal nanocrystals were synthesized as previously described by Murray et al., J. Am. Chem. Soc., v. 113, 8706 (1993), by Dabbousi et al., J. Phys. Chem. B, v. 101, 9463 (1997), and by Qu et al., J. Am. Chem. Soc., v. 124, 2049 (2002).

### EXAMPLE 1

ZnS-capped CdSe nanocrystal quantum dots (NQDs) were synthesized according to the procedures of Murray et al., J Am Chem Soc, 115, 8706 (1993) and Dabbousi et al., J. Phys. Chem. B, 13, 101 (46), 9463 (1997). Thin films of CdSe/ZnS core/shell NQDs capped with trioctylphosphine oxide (TOPO) and trioctylphosphine (TOP) ligands were deposited onto MOCVD-grown, Mg-doped, p-type GaN films on sapphire (available from Emcore Corp., 145 Belmont Drive Somerset, N.J. 08873 USA) using spin coating, drop casting, or Langmuir-Blodgett (LB) techniques as described by Dabbousi et al., Chem. Mater., 6(2), 216 (1994) and Achermann et al., J. Phys. Chem. B, 107 (50), 13782 (2003). LB vertical deposition and horizontal lifting methods were utilized to transfer multiple layers samples of the same-sized NQDs (PL=620 nm) and bilayer samples comprising NQDs of different sizes. NQD samples with average thicknesses of one to three layers were prepared by drop casting or spin coating dilute solutions of NQDs in organic solvents like hexane, octane, and chloroform.

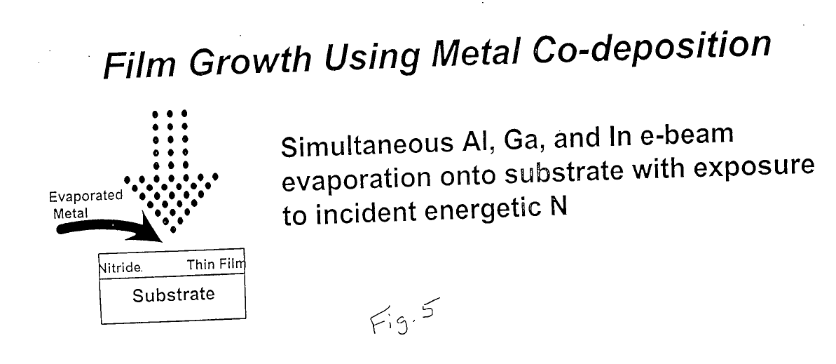

Following the application of the quantum dot layer, the substrates were introduced into a thin film deposition chamber, and heated to temperatures as high as 300° C. prior to being overcoated with n-GaN. Low temperature GaN deposition was achieved by the energetic neutral atom beam lithography/epitaxy (ENABLE) technique that, in the case of nitride films, exposed the substrate to simultaneous fluxes of evaporated gallium metal and atomic species of nitrogen having kinetic energies tunable between about 0.5 eV and about 3.0 eV using an atomic beam source described previously by Cross et al. Simultaneous deposition of Ga metal by e-beam evaporation results in the deposition of polycrystalline hexagonal GaN films as verified by X-ray diffraction measurements. FIG. 4 shows a graph comparing electroluminescence (EL) and photoluminescence (PL) spectra from such a quantum dot diode. FIG. 6 shows a graph illustrating EL intensity versus voltage and current from such a quantum dot diode. The electroluminescence spectra show amost exclusive carrier recombination within the quantum dot as linear scaling of luminescence intensity with current (inset) indicates carrier injection into the dots as opposed to exiton transfer.

Using different size CdSe quantum dots, the light emitting devices yielded red light, green light and orange light.

Although the present invention has been described with reference to specific details, it is not intended that such details should be regarded as limitations upon the scope of the invention, except as and to the extent that they are included in the accompanying claims.

1. A light emitting device comprising:
a first layer of a semiconductor material selected from the group consisting of a p-type semiconductor and a n-type semiconductor;
a layer of colloidal nanocrystals on said first layer of a semiconductor material; and,
a second layer of a semiconductor material selected from the group consisting of a p-type semiconductor and a n-type semiconductor on said layer of colloidal nanocrystals, said second layer of a semiconductor material characterized either as being of a p-type semiconductor where said first layer of a semiconductor material is a n-type semiconductor or as being of a n-type semiconductor where said first layer of a semiconductor material is a p-type semiconductor.

2. The device of claim 1 wherein said first and second layer of a semiconductor material form a p-i-n junction.

3. The device of claim 1 wherein said first layer is on a substrate of a material selected from the group consisting of sapphire, silicon carbide, and silicon.

4. The device of claim 1 wherein said colloidal nanocrystals are selected from the group consisting of ZnS, ZnSe, ZnTe, CdS, CdSe, CdTe, HgS, HgSe, HgTe, AlN, AlP, AlAs, AlSb, GaN, GaP, GaAs, GaSb, InN, InP, InAs, InSb, TlN, TlP, TlAs, TlSb, PbS, PbSe, PbTe, and combinations thereof.

5. The device of claim 1 wherein said first layer is a p-type semiconductor and said second layer is a n-type semiconductor.

6. The device of claim 1 wherein said p-type semiconductor is a doped GaN.

7. The device of claim 1 wherein said n-type semiconductor is selected from the group consisting of GaN, AlN, InN, AlGaN, InGaN, and AlInGaN.

8. A light emitting device comprising:
an injection layer including colloidal nanocrystals embedded in an semiconductor material selected from the group consisting of a p-type semiconductor and a n-type semiconductor.

9. The device of claim 1 wherein said n-type semiconductor or said p-type semiconductor is GaN based.

10. The device of claim 7 wherein said colloidal nanocrystals are selected from the group consisting of ZnS, ZnSe, ZnTe, CdS, CdSe, CdTe, HgS, HgSe, HgTe, AlN, AlP, AlAs, AlSb, GaN, GaP, GaAs, GaSb, InN, InP, InAs, InSb, TlN, TlP, TlAs, TlSb, PbS, PbSe, PbTe, and combinations thereof.
